(19) United States
(12) Patent Application Publication
(10) Pub. No.: US 2022/0294399 A1
(43) Pub. Date: Sep. 15, 2022

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Yoshiharu NITO, Yokohama Kanagawa (JP); Maomi KATSUMATA, Tokyo (JP)

(21) Appl. No.: 17/472,336

(22) Filed: Sep. 10, 2021

(30) Foreign Application Priority Data
Mar. 15, 2021 (JP) 2021-041529

(51) Int. Cl. H03F 3/195; H03F 3/72; H03F 3/24

(52) U.S. Cl. CPC H03F 3/195; H03F 3/72; H03F 3/245; H03F 2200/451; H03F 2200/294; H03F 2203/7221; H03F 2203/7215

(57) ABSTRACT

According to an embodiment, a semiconductor device includes a radio-frequency amplifier circuit, a first switch, a second switch, and a third switch. The first switch is coupled between a first node and an input end of the radio-frequency amplifier circuit. The second switch is coupled between the first node and an output end of the radio-frequency amplifier circuit. The third switch is coupled between the first node and a reference potential node. A control end of the third switch is coupled to one of the first node and the reference potential node.

### CROSS-REFERENCE TO RELATED APPLICATIONS

This application is based upon and claims the benefit of priority from Japanese Patent Application No. 2021-041529, filed Mar. 15, 2021, the entire contents of which are incorporated herein by reference.

### FIELD

Embodiments described herein relate generally to a semiconductor device.

### BACKGROUND

An amplifier circuit used in a mobile terminal or the like is known.

### BRIEF DESCRIPTION OF THE DRAWINGS

FIG. 1 is a block diagram showing an example of the configuration of a wireless device including an amplifier circuit according to a first embodiment.

FIG. 2 shows an example of the circuit configuration of the amplifier circuit according to the first embodiment.

FIG. 3 is a diagram illustrating the threshold voltages of three switches of a bypass switch of the amplifier circuit according to the first embodiment, and the voltages of control signals input to these switches.

FIG. 4 shows an example of the circuit configuration of a radio-frequency low noise amplifier included in the amplifier circuit according to the first embodiment.

FIG. 5 is a diagram schematically illustrating an operation in which the amplifier circuit according to the first embodiment transmits a radio-frequency signal between input and output terminals via the bypass switch.

FIG. 6 shows an example of a graph in which the value of output power when a radio-frequency signal is transmitted via the bypass switch in the amplifier circuit according to the first embodiment is plotted while varying the value of input power.

FIG. 7 shows an example of the circuit configuration of an amplifier circuit according to a comparative example of the first embodiment.

FIG. 8 shows an example of the circuit configuration of an amplifier circuit according to a second embodiment.

FIG. 9 shows an example of a graph in which the value of output power when a radio-frequency signal is transmitted via a bypass switch in the amplifier circuit according to the second embodiment is plotted while varying the value of input power.

FIG. 10 shows an example of the circuit configuration of an amplifier circuit according to a third embodiment.

FIG. 11 shows an example of a graph in which the value of output power when a radio-frequency signal is transmitted via a bypass switch in the amplifier circuit according to the third embodiment is plotted while varying the value of input power.

### DETAILED DESCRIPTION

In general, according to an embodiment, a semiconductor device includes a radio-frequency amplifier circuit, a first switch, a second switch, and a third switch. The first switch is coupled between a first node and an input end of the radio-frequency amplifier circuit. The second switch is coupled between the first node and an output end of the radio-frequency amplifier circuit. The third switch is coupled between the first node and a reference potential node. A control end of the third switch is coupled to one of the first node and the reference potential node.

Hereinafter, embodiments will be described with reference to the accompanying drawings. In the following description, constituent elements having the same function and configuration will be assigned a common reference symbol. When multiple constituent elements with a common reference symbol need to be distinguished from one another, suffixes are added after the common reference symbol for distinction. When the constituent elements need not be particularly distinguished from one another, the constituent elements are assigned only the common reference symbol without suffixes.

Each function block can be implemented in the form of hardware, software, or a combination thereof. The function blocks are not necessarily separated from one another as described below. For example, some functions may be executed by function blocks different from those described as an example. In addition, the function block described as an example may be divided into smaller function sub-blocks. The names of the function blocks and constituent elements in the following description are assigned for convenience, and do not limit the configurations or operations of the function blocks and constituent elements.

### First Embodiment

A semiconductor device according to a first embodiment will be described below. Hereinafter, the semiconductor device will also be referred to as an amplifier circuit 1.

### Configuration Example

(1) Wireless Device

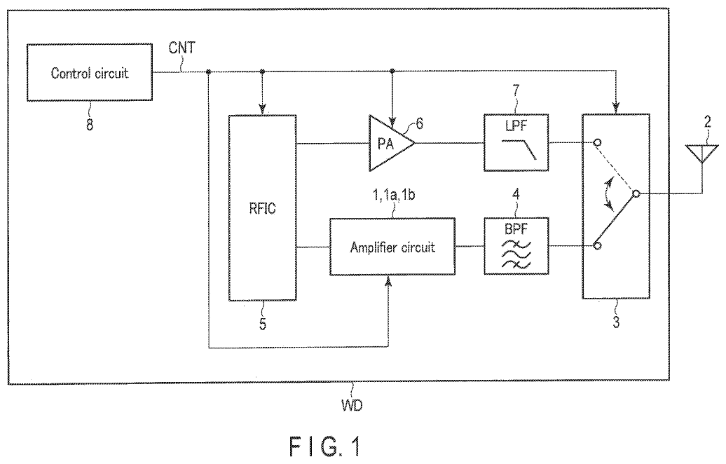

FIG. 1 is a block diagram showing an example of the configuration of a wireless device WD including the amplifier circuit 1 according to the first embodiment. The wireless device WD is, for example, a smartphone, a feature phone, a mobile terminal (such as a tablet terminal), a personal computer, a game device, a router, or a base station. The wireless device WD transmits and receives signals using a communication standard such as long term evolution (registered trademark; LTE) and/or Wifi. The reference symbols 1a and 1b shown in FIG. 1 will be described in subsequent embodiments.

The amplifier circuit 1 is, for example, a radio-frequency amplifier circuit. Hereinafter, descriptions will be provided assuming that the amplifier circuit 1 includes a radio-frequency low noise amplifier (LNA).

The wireless device WD includes, for example, an antenna 2, an antenna switch 3, a band-pass filter (BPF) 4, a radio-frequency (RF) integrated circuit (IC) 5, a power amplifier (PA) 6, a low-pass filter (LPF) 7, and a control circuit 8, in addition to the amplifier circuit 1.

The antenna 2 receives radio-frequency signals from another device (such as a base station or another wireless device). The antenna 2 also enables transmission of radio-frequency signals from the wireless device WD to another device.

The antenna switch 3 is a switch circuit that switches between the wireless device WD transmitting signals to another device via the antenna 2 and the wireless device WD receiving signals from another device via the antenna 2. FIG. 1 shows an example in which the transmission signal path and the reception signal path each consist of a single line. However, the transmission signal path and the reception signal path may each consist of a plurality of lines capable of transmitting signals in a plurality of frequency bands. The antenna switch 3 may be provided on the same substrate (such as a silicon-on-insulator (SOI) substrate) as the amplifier circuit 1 to form one chip with the amplifier circuit 1. Providing the antenna switch 3 and the amplifier circuit 1 on the same substrate may realize reduction in a power loss of a radio-frequency signal, reduction in power consumption, and/or reduction in a circuit area.

The band-pass filter 4 receives radio-frequency signals via the antenna 2 and the antenna switch 3. The band-pass filter 4 selectively allows radio-frequency signals of frequencies that fall within a certain range among the radio-frequency signals to pass therethrough.

The amplifier circuit 1 receives, at an input terminal, the radio-frequency signals that have passed through the band-pass filter 4. The frequencies of the radio-frequency signals fall within a range set by the communication standard, such as LTE and/or Wifi, used by the wireless device WD, and are greater than or equal to 300 megahertz (MHz), for example. The amplifier circuit 1, for example, amplifies the radio-frequency signals, and outputs the amplified radio-frequency signals from an output terminal.

The radio-frequency integrated circuit 5 receives the radio-frequency signals output from the amplifier circuit 1, and executes various types of processing on the radio-frequency signals. The radio-frequency integrated circuit 5, for example, transmits the radio-frequency signals after being subjected to such processing to the power amplifier 6.

The power amplifier 6 receives the radio-frequency signals transmitted from the radio-frequency integrated circuit 5. The power amplifier 6 amplifies the radio-frequency signals, and outputs the amplified radio-frequency signals.

The low-pass filter 7 receives the radio-frequency signals output from the power amplifier 6. The low-pass filter 7 selectively allows radio-frequency signals of frequencies lower than or equal to a certain value among the radio-frequency signals to pass therethrough. The radio-frequency signals that have passed through the low-pass filter 7 are transmitted to the outside of the wireless device WD via the antenna switch 3 and the antenna 2.

The control circuit 8, for example, transmits control signals CNT to the amplifier circuit 1, the antenna switch 3, the radio-frequency integrated circuit 5, and the power amplifier 6, respectively. Based on the control signal CNT, the amplifier circuit 1, the antenna switch 3, the radio-frequency integrated circuit 5, and the power amplifier 6 each perform processing. The control circuit 8 may be provided in the radio-frequency integrated circuit 5.

Alternatively, the radio-frequency integrated circuit 5 may have the function of the control circuit 8.

(2) Amplifier Circuit

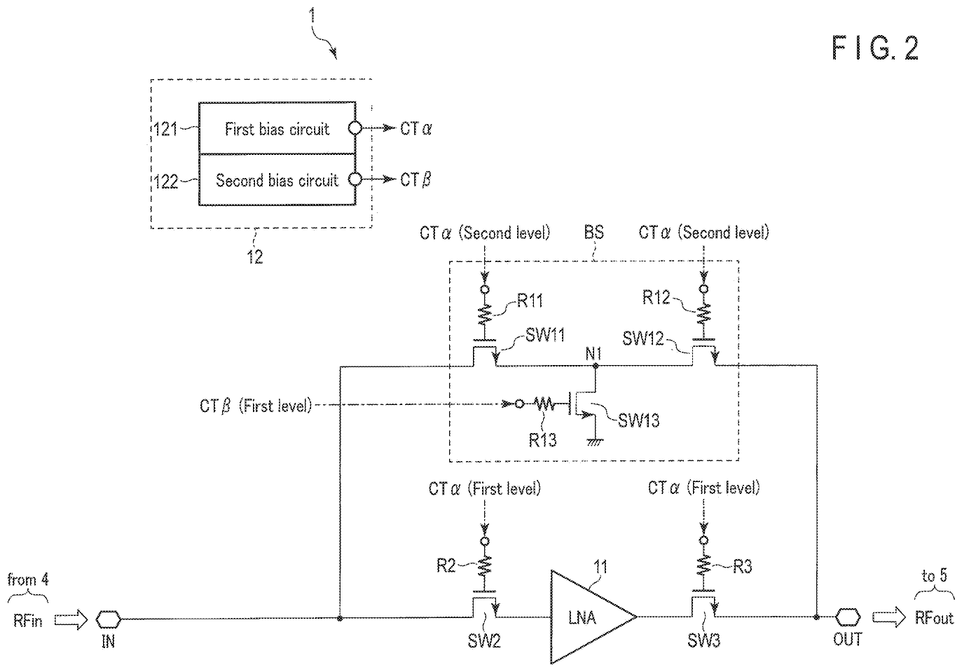

FIG. 2 shows an example of the circuit configuration of the amplifier circuit 1 according to the first embodiment.

The amplifier circuit 1 includes, for example, a radio-frequency low noise amplifier circuit (LNA) 11, a bypass switch BS, switches SW2 and SW3, resistors R2 and R3, and a control signal generator 12. In FIG. 2, the input terminal and output terminal of the amplifier circuit 1 are shown as terminal IN and terminal OUT.

The control signal generator 12 includes a first bias circuit 121. The first bias circuit 121, for example, generates a control signal CTα based on the control signal CNT from the control circuit 8. The control signal CTα includes a high (H)-level voltage signal and a low (L)-level voltage signal. Hereinafter, when the term “level” is used, the “level” refers to a voltage level, as long as there is no particular description to the contrary. The first bias circuit 121, for example, transmits one of the H-level signal (hereinafter referred to as an “H-level control signal CTα”) and the L-level signal (hereinafter referred to as an “L-level control signal CTα”) of the control signal CTα to each of the bypass switch BS and switches SW2 and SW3.

A first end of the switch SW2 is coupled to the terminal IN, and a second end of the switch SW2 is coupled to an input terminal of the radio-frequency low noise amplifier 11.

Signals can be transmitted between the first end and the second end while the switch SW2 is in the on-state. The switch SW2 is, for example, a field effect transistor (FET) such as an n-channel metal oxide semiconductor (MOS). Herein, descriptions will be provided assuming that the switch SW2 is an n-channel MOS transistor. The same applies to the other switches SW as long as there is no particular description to the contrary.

The control signal CTα on either level is input to the control gate (hereinafter also referred to as a “gate” or a “control end”) of the switch SW2. The switch SW2 is in the off-state while the L-level control signal CTα is input thereto, and is in the on-state while the H-level control signal CTα is input thereto.

The gate of the switch SW2 is coupled to one end of the resistor R2. The aforementioned input of the control signal CTα to the gate of the switch SW2 is implemented by input of the control signal CTα to the other end of the resistor R2. Input of a control signal to the gate of each of the other switches SW is also made through a resistor coupled to the switch SW as long as there is no particular description to the contrary.

An output terminal of the radio-frequency low noise amplifier 11 is coupled to a first end of the switch SW3, and a second end of the switch SW3 is coupled to the terminal OUT. The gate of the switch SW3 is coupled to one end of the resistor R3. The control signal CTα on the same level as that input to the gate of the switch SW2 is input to the other end of the resistor R3. The switch SW3 is thereby controlled, for example, to be in the on-state while the switch SW2 is in the on-state and to be in the off-state while the switch SW2 is in the off-state.

In this manner, the terminal IN and terminal OUT can be electrically coupled to each other via the switch SW2, radio-frequency low noise amplifier 11, and switch SW3. Another path that enables electrical coupling between the terminal IN and the terminal OUT will be described.

A first end of the bypass switch BS is coupled to the terminal IN, and a second end of the bypass switch BS is coupled to the terminal OUT. The bypass switch BS is controlled by the control signal CTα transmitted to the bypass switch BS, for example to be in the off-state while the switch SW2 is in the on-state and to be in the on-state while the switch SW2 is in the off-state.

First, the case where the switches SW2 and SW3 are controlled to be in the on-state and the bypass switch BS is controlled to be in the off-state will be described. Such control is performed, for example, when a radio-frequency power Pin relating to a radio-frequency signal RFin which has passed through the band-pass filter 4 and been input to the terminal IN is smaller than or equal to a certain value. Namely, when the radio-frequency power Pin is smaller than or equal to this value, the H-level control signal CTα is input to the gate of the switch SW2.

The radio-frequency signal RFin input to the terminal IN is input to the input terminal of the radio-frequency low noise amplifier 11 via the switch SW2. The radio-frequency low noise amplifier 11 amplifies the radio-frequency signal RFin input to the input terminal while suppressing a decrease in the signal-to-noise ratio, and outputs the amplified radio-frequency signal from the output terminal. The output radio-frequency signal is output from the terminal OUT via the switch SW3. In FIG. 2, the radio-frequency signal output from the terminal OUT is shown as a radio-frequency signal RFout.

Next, the case where the bypass switch BS is controlled to be in the on-state and the switches SW2 and SW3 are controlled to be in the off-state will be described. Such control is performed, for example, when the radio-frequency power Pin is larger than the certain value. Namely, when the radio-frequency power Pin is larger than this value, the L-level control signal CTα is input to the gate of the switch SW2.

The radio-frequency signal RFin input to the terminal IN is routed through the bypass switch BS in the on-state, and is thereby output from the terminal OUT without being amplified by the radio-frequency low noise amplifier 11.

Hereinafter, the amplifier circuit 1 is also described as being in an amplifying mode while the switches SW2 and SW3 are controlled to be in the on-state and the bypass switch BS is controlled to be in the off-state. In contrast, the amplifier circuit 1 is also described as being in a bypass mode while the bypass switch BS is controlled to be in the on-state and the switches SW2 and SW3 are controlled to be in the off-state.

(3) Bypass Switch

Details of the bypass switch BS will be described together with details of the control signal generator 12, with continuous reference to FIG. 2.

The control signal generator 12 further includes a second bias circuit 122. The second bias circuit 122, for example, generates a control signal CTβ based on the control signal CNT. The control signal CTβ includes an H-level voltage signal and an L-level voltage signal. The second bias circuit 122, for example, transmits one of the H-level signal (hereinafter referred to as an “H-level control signal CTβ”) and the L-level signal (hereinafter referred to as an “L-level control signal CTβ”) of the control signal CTβ to the bypass switch BS.

The bypass switch BS includes, for example, a switch SW11, a resistor R11, a switch SW12, a resistor R12, a switch SW13, and a resistor R13. The bypass switch BS functions as a so-called T-type switch in which, for example, the switches SW11 and SW12 are used as so-called through switches and the switch SW13 is used as a so-called shunt switch.

A first end of the switch SW11 is coupled to the terminal IN. This coupling implements the above-described coupling between the first end of the bypass switch BS and the terminal IN. A second end of the switch SW11 is coupled to a node N1. The gate of the switch SW11 is coupled to one end of the resistor R11. The control signal CTα on the opposite level to that input to the gate of the switch SW2 is input to the other end of the resistor R11. The switch SW11 is thereby controlled, for example, to be in the off-state while the switch SW2 is in the on-state and to be in the on-state while the switch SW2 is in the off-state.

A first end of the switch SW12 is coupled to the node N1. A second end of the switch SW12 is coupled to the terminal OUT. This coupling implements the above-described coupling between the second end of the bypass switch BS and the terminal OUT. The gate of the switch SW12 is coupled to one end of the resistor R12. The control signal CTα on the opposite level to that input to the gate of the switch SW2 is input to the other end of the resistor R12. Accordingly, the switch SW12 is also controlled, for example, to be in the off-state while the switch SW2 is in the on-state and to be in the on-state while the switch SW2 is in the off-state.

A first end of the switch SW13 is coupled to the node N1. A second end of the switch SW13 is, for example, grounded. Hereinafter, descriptions will be provided assuming that the second end of the switch SW13 is grounded so that a voltage of 0 volts (V) is applied to the second end. The gate of the switch SW13 is coupled to one end of the resistor R13. The control signal CTβ on the same level as the control signal CTα input to the gate of the switch SW2 is input to the other end of the resistor R13. Each constituent element described as being grounded herein does not necessarily have to be grounded, for example the constituent element need not be grounded if it is at a low reference potential among several reference potentials used in the circuit including the constituent element. A node coupled to a constituent element to control the constituent element to be at a reference potential as described above will also be referred to as a “reference potential node”.

The above-described off-state of the bypass switch BS is implemented by input of the L-level control signal CTα to the gates of the switches SW11 and SW12 and input of the H-level control signal CTβ to the gate of the switch SW13. The off-state of the bypass switch BS will be described.

The switches SW11 and SW12 with their gates supplied with the L-level control signal CTα are in the off-state, whereas the switch SW13 with its gate supplied with the H-level control signal CTβ is in the on-state. The node N1 is grounded.

The above-described on-state of the bypass switch BS is implemented by input of the H-level control signal CTα to the gates of the switches SW11 and SW12 and input of the L-level control signal CTβ to the gate of the switch SW13. The on-state of the bypass switch BS will be described.

The switches SW11 and SW12 with their gates supplied with the H-level control signal CTα are in the on-state. Since the switches SW11 and SW12 are in the on-state, signals can be transmitted between the terminal IN and the terminal OUT. The switch SW13 can adjust the voltage of the radio-frequency signal RFin based on, for example, the potential (hereinafter also referred to as a “voltage”) of the node N1 coupled to the first end of the switch SW13. Details will be described below. The switch SW13 is in the off-state while the voltage of the node N1 is smaller than a certain value, which enables transmission of the radio-frequency signal RFin input to the terminal IN to the terminal OUT via the bypass switch BS without adjustment of the voltage of the radio-frequency signal RFin. The switch SW13 is in the on-state while the voltage of the node N1 is larger than or equal to the certain value, which enables adjustment of the voltage of the radio-frequency signal RFin and transmission of the adjusted radio-frequency signal to the terminal OUT.

The switch SW13 is intended to adjust the voltage of the radio-frequency signal RFin in this manner. To serve this purpose, the switch SW13 is intended to be turned on or off based on the voltage of the node N1 while receiving the L-level control signal CTβ. The magnitude of the threshold voltage of the switch SW13 and the voltage of the L-level control signal CTβ are determined so as to enable such an operation.

Specifically, the magnitude of the threshold voltage of the switch SW13 and the voltage of the L-level control signal CTβ are determined based on the assumed variation range of the voltage of the node N1 so that the switch SW13 receiving the L-level control signal CTβ can be in the on-state. That is, as will be described in detail later, the gate of the switch SW13 is influenced by the voltage of the node N1 because of the parasitic capacitance, etc. between the first end and gate of the switch SW13. Therefore, the voltage of the gate of the switch SW13 is a sum of the voltage of the L-level control signal CTβ and half of the voltage of the node N1. The switch SW13 can be in the on-state based on this voltage of the gate, and the on-state switch SW13 lowers the voltage of the node N1. In accordance with the drop of the voltage of the node N1, the power relating to the radio-frequency signal RFout decreases. In this way, the power relating to the radio-frequency signal RFout can be prevented from exceeding a certain value. With the above taken into consideration, the magnitude of the threshold voltage of the switch SW13 and the voltage of the L-level control signal CTβ are determined.

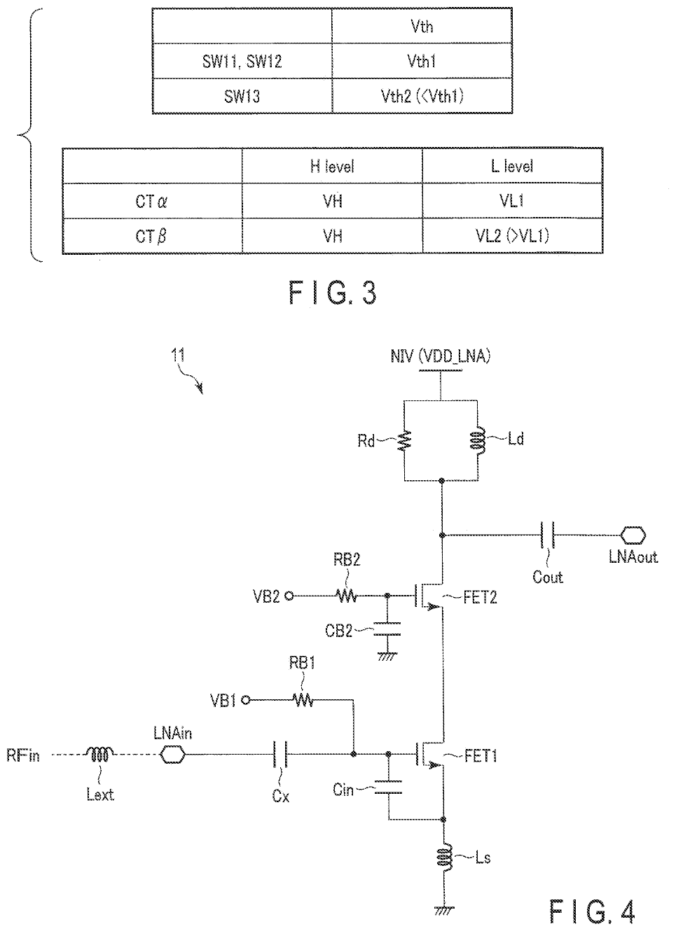

FIG. 3 is a diagram illustrating the threshold voltages of the three switches SW11, SW12, and SW13 of the bypass switch BS of the amplifier circuit 1 according to the first embodiment, and the voltages of the control signals CTα and CTβ input to these switches SW.

First, the threshold voltage of each switch SW will be described. The threshold voltage of a switch SW refers to the minimum potential difference between the gate and source of the switch SW, which enables switching of the switch SW from the off-state to the on-state.

The threshold voltages of the switches SW11 and SW12 are, for example, a voltage Vth1. The threshold voltage of the switch SW13 is a voltage Vth2. In order to provide the switch SW13 with the above-described voltage adjustment function, the voltage Vth2 is smaller than the voltage Vth1. For example, (magnitude of voltage Vth2)/(magnitude of voltage Vth1) is not less than ⅓ and not more than ⅚.

Next, the control signals CTα and CTβ will be described.

The voltages of the H-level control signals CTα and CTβ are each a voltage VH. The voltage VH is set so that, for example, the switches SW11 and SW12 are always in the on-state while the control signal of the voltage VH is input to the gates of the switches SW11 and SW12 and so that the switch SW13 is in the on-state while the control signal of the voltage VH is input to the gate of the switch SW13. Specifically, the voltage VH is set so that the potential difference between the gate and source of every switch SW11, SW12, SW13 is sufficiently larger than the threshold voltage of the switch SW while the control signal of the voltage VH is input to the gate of the switch SW.

The voltage of the L-level control signal CTα is a voltage VL1. The voltage VL1 is set so that, for example, the switches SW11 and SW12 are always in the off-state while the control signal of the voltage VL1 is input to the gates of the switches SW11 and SW12. Specifically, the voltage VL1 is set so that the potential difference between the gate and source of either switch SW11, SW12 is sufficiently smaller than the threshold voltage of the switch SW while the control signal of the voltage VL1 is input to the gate of the switch SW. For example, the voltage VL1 is set to a negative value.

The voltage of the L-level control signal CTβ is a voltage VL2. The voltage VL2 is set so that, for example, the switch SW13 has the function of adjusting the voltage of the radio-frequency signal RFin by switching between the on-state and the off-state as described above, while the control signal of the voltage VL2 is input to the gate of the switch SW13. For example, the voltage VL2 is set to a voltage higher than the voltage VL1. The voltage VL2 is set to, for example, a value larger than or equal to 0 when the voltage VL1 has a negative value. For example, (voltage difference between voltage VH and voltage VL2)/(voltage difference between voltage VH and voltage VL1) is not less than ⅓ and not more than ⅚.

Hereinafter, an example of the voltages Vth1, Vth2, VH, VL1 and VL2 will be described together with the resistors R11, R12, R13, etc.

The voltage Vth1 is, for example, 0.7 V, and the voltage Vth2 is, for example, 0.5 V or less, and more specifically, 0.3 V. In this case, for example, the voltage VH is 3 V, the voltage VL1 is −2 V, and the voltage VL2 is 0 V. The resistors R11, R12, and R13 are each, for example, 100 kiloohm (kΩ).

Described above is the case where the threshold voltage of the switch SW13 is smaller than the threshold voltages of the switches SW11 and SW12, and the voltage of the L-level control signal CTβ is higher than the voltage of the L-level control signal CTα. However, the present embodiment is not limited to this. For example, when the threshold voltages of the switches SW11, SW12, and SW13 have the above-described magnitude relationship, the voltages of the L-level control signals CTα and CTβ may be substantially the same. Alternatively, when the voltages of the L-level control signals CTα and CTβ have the above-described magnitude relationship, the threshold voltages of the switches SW11, SW12, and SW13 may be substantially the same.

Described above is the case where the amplifier circuit 1 includes switches SW2 and SW3; however, the present embodiment is not limited to this. The amplifier circuit 1 does not have to include one of the switches SW2 and SW3.

(3) Radio-Frequency Low Noise Amplifier

FIG. 4 shows an example of the circuit configuration of the radio-frequency low noise amplifier 11 included in the amplifier circuit 1 according to the first embodiment. FIG. 4 shows an example of the circuit configuration of a cascode radio-frequency low noise amplifier 11. The circuit configuration shown in FIG. 4 is manufactured, for example, by a silicon on insulator (SOI) complementary metal-oxide-semiconductor (CMOS) process.

The radio-frequency low noise amplifier 11 includes, for example, N-channel MOS transistors FET1 and FET2, capacitance elements (also referred to as capacitors) Cx, Cin, CB2, and Cout, and induction elements (also referred to as inductors) Ls and Ld, and resistors RB1, RB2, and Rd. In FIG. 4, the input terminal and output terminal of the radio-frequency low noise amplifier 11 are shown as terminal LNAin and terminal LNAout.

A first electrode of the capacitance element Cx is coupled to the terminal LNAin, and a second electrode of the capacitance element Cx is coupled to the gate of the transistor FET1.

A first end (e.g., the source) of the transistor FET1 is coupled to one end of the induction element Ls, and a second end (e.g., the drain) of the transistor FET1 is coupled to a first end (e.g., the source) of the transistor FET2. The other end of the induction element Ls is, for example, grounded. A second end (e.g., the drain) of the transistor FET2 is coupled to one end of the induction element Ld, and the other end of the induction element Ld is coupled to a node NIV. Between the second end of the transistor FET2 and the node NIV, the resistor Rd is coupled in parallel with the induction element Ld. For example, a reference voltage VDD_LNA is applied to the node NIV.

The gate of the transistor FET1 is coupled to a first electrode of the capacitance element Cin, and the first end of the transistor FET1 is coupled to a second electrode of the capacitance element Cin. The gate of the transistor FET1 is coupled to one end of the resistor RB1. A voltage VB1 is applied to the other end of the resistor RB1.

The gate of the transistor FET2 is coupled to one end of the resistor RB2. A voltage VB2 is applied to the other end of the resistor RB2. The gate of the transistor FET2 is coupled to a first electrode of the capacitance element CB2. A second electrode of the capacitance element CB2 is, for example, grounded.

The second end of the transistor FET2 is coupled to a first electrode of the capacitance element Cout. A second electrode of the capacitance element Cout is coupled to the terminal LNAout.

The transistor FET1 functions as a source ground FET having inductive source degeneration by the induction element Ls. The transistor FET2 functions as a gate ground FET since the second electrode of the capacitance element CB2 whose first electrode is coupled to the gate of the transistor FET2 is grounded.

For example, an induction element Lext is provided outside the radio-frequency low noise amplifier 11. Specifically, the induction element Lext is provided on the path through which the radio-frequency signal RFin is transmitted to the radio-frequency low noise amplifier 11 after being routed through the switch SW2, although not shown in FIG. 2. The induction element Lext, the capacitance elements Cx and Cin, and the induction element Ls constitute, for example, an input matching circuit. The input matching circuit achieves impedance matching in consideration of gain matching and noise matching of the transistors FET1 and FET2. The capacitance element Cx may function to cut a direct current (DC). The capacitance element Cin may not be provided.

The resistor Rd, the induction element Ld, and the capacitance element Cout constitute, for example, an output matching circuit. The resistor Rd contributes to, for example, gain adjustment and stabilization.

The voltages VB1 and VB2 are generated and supplied by a bias voltage generator (not shown) included in the radio-frequency low noise amplifier 11, for example. The resistors RB1 and RB2, for example, prevent radio-frequency signals from going around to the bias voltage generator.

The above configuration enables the radio-frequency low noise amplifier 11 to amplify radio-frequency signals input to the terminal LNAin while suppressing a decrease in the signal-to-noise ratio, and output amplified radio-frequency signals from the terminal LNAout.

### Operation Example

Hereinafter, an operation example will be described in detail, in which the amplifier circuit 1 according to the first embodiment, while in the bypass mode, transmits a radio-frequency signal RFin from the terminal IN to the terminal OUT via the bypass switch BS without amplifying the radio-frequency signal RFin with the radio-frequency low noise amplifier 11.

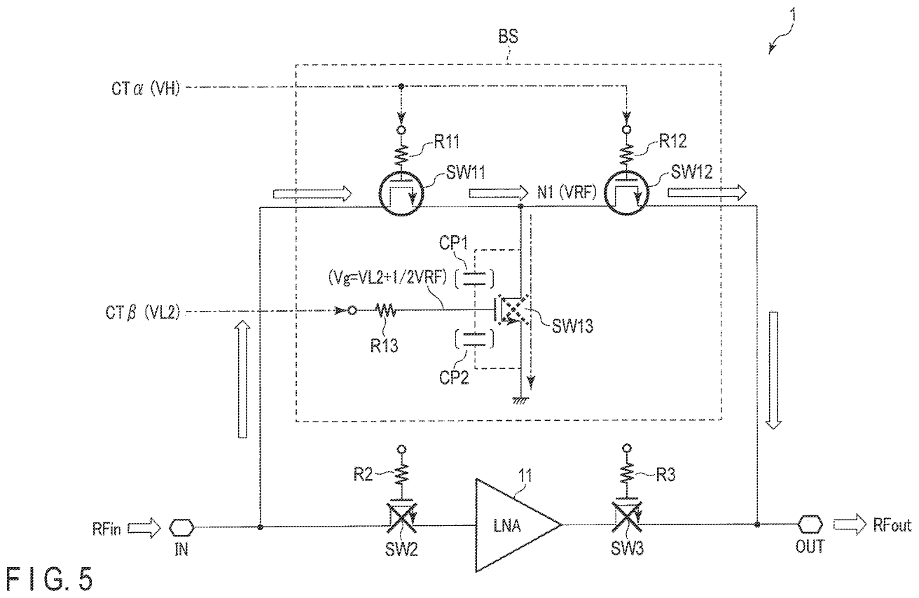

FIG. 5 is a diagram schematically illustrating the operation in which the amplifier circuit 1 according to the first embodiment transmits the radio-frequency signal RFin from the terminal IN to the terminal OUT via the bypass switch BS.

For example, the case where the radio-frequency power Pin relating to the radio-frequency signal RFin exceeds the certain value will be described.

The first bias circuit 121 inputs the L-level control signal CTα to the gates of the switches SW2 and SW3 via the respective resistors R2 and R3. The first bias circuit 121 inputs the H-level control signal CTα to the gates of the switches SW11 and SW12 via the respective resistors R11 and R12. The second bias circuit 122 inputs the L-level control signal CTβ to the gate of the switch SW13 via the resistor R13.

Accordingly, the switches SW2 and SW3 are brought into the off-state, and the switches SW11 and SW12 are brought into the on-state.

Since the switches SW2 and SW3 are in the off-state while the switches SW11 and SW12 are in the on-state, the radio-frequency signal RFin input to the terminal IN is transmitted to the node N1 via the on-state switch SW11. Hereinafter, the voltage of the node N1 will be referred to as a voltage VRF.

A parasitic capacitance CP1 occurs between the gate of the switch SW13 and the first end of the switch SW13. A parasitic capacitance CP2 occurs between the gate of the switch SW13 and the second end of the switch SW13. The parasitic capacitances CP1 and CP2 are, for example, substantially equal to each other. In this case, the voltage Vg of the gate of the switch SW13 is a sum of the voltage VL2 of the L-level control signal CTβ and half of the voltage VRF. The voltage Vg is also a potential difference between the gate and source of the switch SW13. As the voltage VRF increases, the voltage Vg also increases.

When the voltage Vg is smaller than the voltage Vth2, which is the threshold voltage of the switch SW13, the switch SW13 is in the off-state. In this case, the switch SW13 does not adjust the voltage of the radio-frequency signal RFin being transmitted to the node N1.

When the voltage Vg is larger than or equal to the voltage Vth2, the switch SW13 is in the on-state. Since a current flows out of the node N1 via the on-state switch SW13, the voltage VRF of the node N1 drops. The drop of the voltage VRF by the switch SW13 continues until, for example, the voltage Vg falls below the voltage Vth2. In this way, the voltage VRF is adjusted by the on-state switch SW13 and, for example, peaks of the voltage VRF on the high potential side is cut.

The voltage VRF accordingly adjusted by the switch SW13 as appropriate is transmitted to the terminal OUT via the on-state switch SW12, and the radio-frequency signal RFout is output from the terminal OUT. The power relating to the adjusted radio-frequency signal RFout is smaller than the power relating to the unadjusted radio-frequency signal RFin.

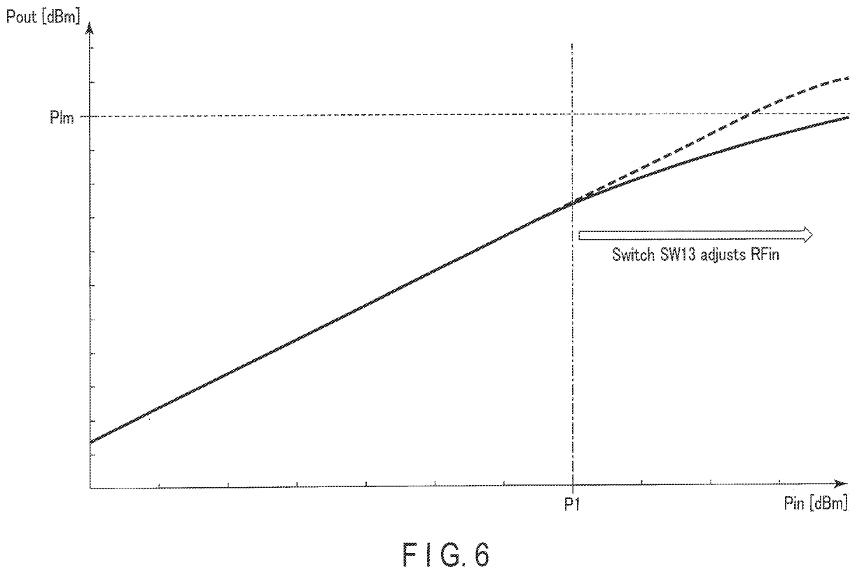

FIG. 6 shows an example of a graph in which the value of the radio-frequency power Pout (hereinafter also referred to as an “output power Pout”) relating to the radio-frequency signal RFout in the case where the radio-frequency signal RFin is transmitted via the bypass switch BS in the amplifier circuit 1 according to the first embodiment is plotted while varying the value of the radio-frequency power Pin (hereinafter also referred to as an “input power Pin”) relating to the radio-frequency signal RFin. The horizontal axis represents the value of the input power Pin. The vertical axis represents the value of the output power Pout. In FIG. 6, the graph is shown as a solid line. The broken-line graph shown in FIG. 6 will be described in the section of advantageous effects.

The solid-line graph shown in FIG. 6 represents values under the condition that the frequency of the radio-frequency signal RFin takes substantially a fixed value. In the graph, the values of the input power Pin and output power Pout expressed in units of decibel milliwatts (dBmW; hereinafter referred to as dBm) are plotted. dBm is a unit used for expressing power as a decibel (dB) value with a reference value of one milliwatt (mW). The horizontal axis and vertical axis are each calibrated in 5 dBm increments. The other graphs in the other similar drawings show values under the same condition. Hereinafter, the value of a power refers to a value of the power expressed in the units of dBm.

As shown in FIG. 6, when the value of the input power Pin is smaller than a value P1, the value of the output power Pout increases in accordance with a linear function as the value of the input power Pin increases. Details will be described below. When the value of the input power Pin increases by, for example, 5 dBm, the value of the output power Pout also increases by 5 dBm. The value of the output power Pout is, for example, smaller than the value of the input power Pin only by a certain amount of power lost as a transmission loss. Since the slope of the solid-line graph is 1, the value of the output power Pout expressed in units of mW also increases in accordance with a linear function as the value of the input power Pin expressed in units of mW increases.

When the value of the input power Pin is larger than or equal to P1, the graph is as follows. As described above, the switch SW13 adjusts the radio-frequency signal RFin. Accordingly, as shown in FIG. 6, the increase in the value of the output power Pout becomes smaller than the increase in the value of the input power Pin, and the value of the output power Pout does not exceed a certain value Plm even though the value of the input power Pin increases. P1 and Plm may be changed based on, for example, the voltage Vth2 and the voltage VL2. For example, Plm is set so as not to exceed the withstand voltage of the circuit in the subsequent stage which is coupled to the terminal OUT of the amplifier circuit 1. The withstand voltage of the circuit in the subsequent stage is, for example, 15 dBm.

The above-described configuration and operation of the amplifier circuit 1 are mere examples. For example, the circuit configuration of the radio-frequency low noise amplifier 11 is not limited to the one shown in FIG. 4. In addition, the switches SW2 and SW3 are described above as structures that prevent the radio-frequency signal RFin from being routed through the radio-frequency low noise amplifier 11 when the radio-frequency signal RFin is transmitted from the terminal IN to the terminal OUT via the bypass switch BS. However, the amplifier circuit 1 does not have to include, for example, one of the switches SW2 and SW3. Alternatively, the amplifier circuit 1 may include another structure that may perform a function similar to that of the switches SW2 and SW3. The same applies to the other embodiments.

### Advantageous Effects

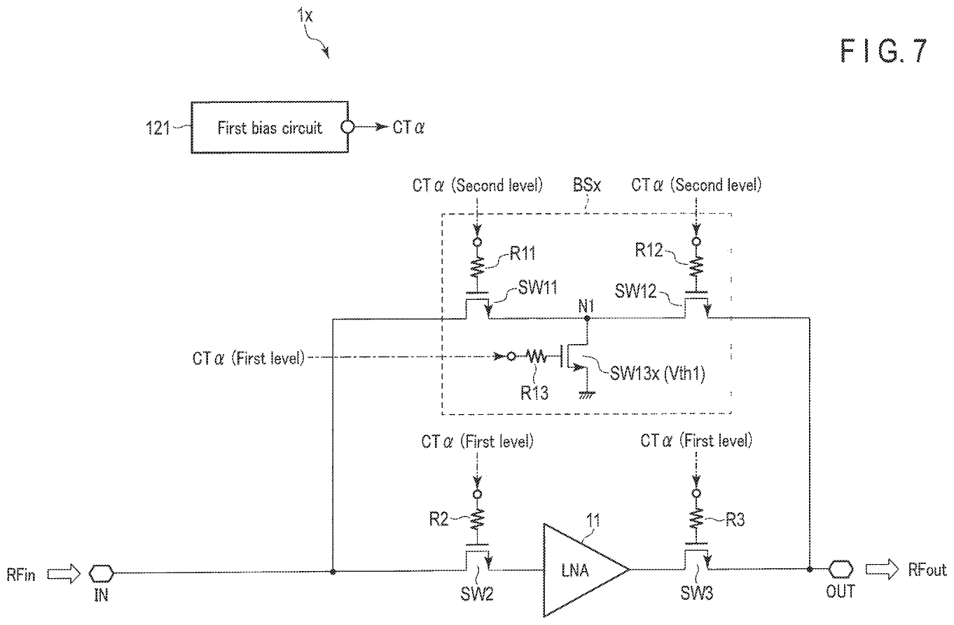

FIG. 7 shows an example of the circuit configuration of an amplifier circuit 1x according to a comparative example of the first embodiment.

The circuit configuration of the amplifier circuit 1x shown in FIG. 7 differs from that of the amplifier circuit 1 shown in FIG. 2 in that the amplifier circuit 1x includes a bypass switch BSx instead of the bypass switch BS, and does not include the second bias circuit 122. The description of the coupling relationship of the bypass switch BS applies to the coupling relationship of the bypass switch BSx.

The circuit configuration of the bypass switch BSx differs from that of the bypass switch BS in that the bypass switch BSx includes a switch SW13x instead of the switch SW13. The description of the coupling relationship of the switch SW13 applies to the coupling relationship of the switch SW13x.

The threshold voltage of the switch SW13x is the voltage Vth1, which is the same as the threshold voltages of the switches SW11 and SW12. Instead of the control signal CTβ in the example of FIG. 2, the control signal CTα at the same level as that input to the gate of the switch SW2 is input to the gate of the switch SW13x via the resistor R13.

As in the example of FIG. 5, the case where the amplifier circuit 1x transmits a radio-frequency signal RFin from the terminal IN to the terminal OUT via the bypass switch BSx will be described.

The switches SW2 and SW3 are brought into the off-state, and the switches SW11 and SW12 are brought into the on-state. The radio-frequency signal RFin is transmitted to the node N1 via the on-state switch SW11.

As described with reference to FIG. 5, the voltage of the gate of the switch SW13x is a sum of the voltage VL1 of the L-level control signal CTα and half of the voltage VRF. Since the voltage VL1 is lower than the voltage VL2, the voltage of the gate of the switch SW13x is lower than the voltage Vg of the gate of the switch SW13 in the example of FIG. 5. In addition, the voltage Vth1, which is the threshold voltage of the switch SW13x, is larger than the voltage Vth2, which is the threshold voltage of the switch SW13. Therefore, unlike the switch SW13, the switch SW13x is always in the off-state, and thus does not adjust the voltage of the radio-frequency signal RFin being transmitted to the node N1. Accordingly, the voltage VRF is transmitted to the terminal OUT via the on-state switch SW12 without being adjusted by the switch SW13x, and the radio-frequency signal RFout is output from the terminal OUT.

An example of a graph in which the value of the output power Pout in this case is plotted while varying the value of the input power Pin is shown in FIG. 6 by a broken line. Even when the value of the input power Pin is larger than or equal to P1, the switch SW13x does not adjust the radio-frequency signal RFin; therefore, the broken-line graph showing the relationship between the value of the input power Pin and the value of the output power Pout is substantially linear. Therefore, unlike the solid-line graph in FIG. 6, as the value of the input power Pin increases, the value of the output power Pout greatly exceeds the value Plm.

In contrast, in the amplifier circuit 1 according to the first embodiment, the switch SW13 adjusts the radio-frequency signal RFin as appropriate when the radio-frequency signal RFin is transmitted from the terminal IN to the terminal OUT via the bypass switch BS. Specifically, when the voltage Vg of the gate of the switch SW13 is larger than or equal to the voltage Vth2, the switch SW13 is in the on-state and, thus, the voltage VRF of the node N1 is lowered. As a result, the value of the radio-frequency power Pout relating to the radio-frequency signal RFout output from the amplifier circuit 1 can be prevented from exceeding the value Plm. This adjustment can be performed because the voltage Vth2, which is the threshold voltage of the switch SW13, is relatively small and the voltage of the L-level control signal CTβ input to the gate of the switch SW13 is relatively high.

Consequently, the amplifier circuit 1 according to the first embodiment can be prevented from outputting a radio-frequency signal RFout of a power that exceeds the withstand voltage of a circuit, such as a reception signal demodulation circuit, in the stage subsequent to the amplifier circuit 1, and thus can prevent a breakdown of the circuit in the subsequent stage.

In contrast, when the radio-frequency signal RFin is not transmitted from the terminal IN to the terminal OUT via the bypass switch BS, i.e., when the amplifier circuit 1 is in the amplifying mode, the switch SW13 is in the on-state as the H-level control signal CTβ is input to the gate of the switch SW13. The second end of the switch SW13 is, for example, grounded. This enables the switch SW13 to realize electrical isolation between the first end and second end of the bypass switch BS. In the above-described manner, the switch SW13 implements the function of adjusting the radio-frequency signal RFin when the amplifier circuit 1 is in the bypass mode, and the function of providing isolation between the first end and second end of the bypass switch BS when the amplifier circuit 1 is in the amplifying mode. The radio-frequency low noise amplifier 11, the bypass switch BS, and the switches SW2 and SW3 may be formed on the same semiconductor substrate. Therefore, the amplifier circuit 1 may reduce the circuit size of the whole device.

### Second Embodiment

An amplifier circuit 1a according to a second embodiment will be described below.

A configuration of the amplifier circuit 1a according to the second embodiment will be described, focusing on differences from the configuration of the amplifier circuit 1 according to the first embodiment.

The description of the amplifier circuit 1 with reference to FIG. 1 also applies to the amplifier circuit 1a. Specifically, the description of FIG. 1 applies except that the amplifier circuit 1 is replaced with the amplifier circuit 1a.

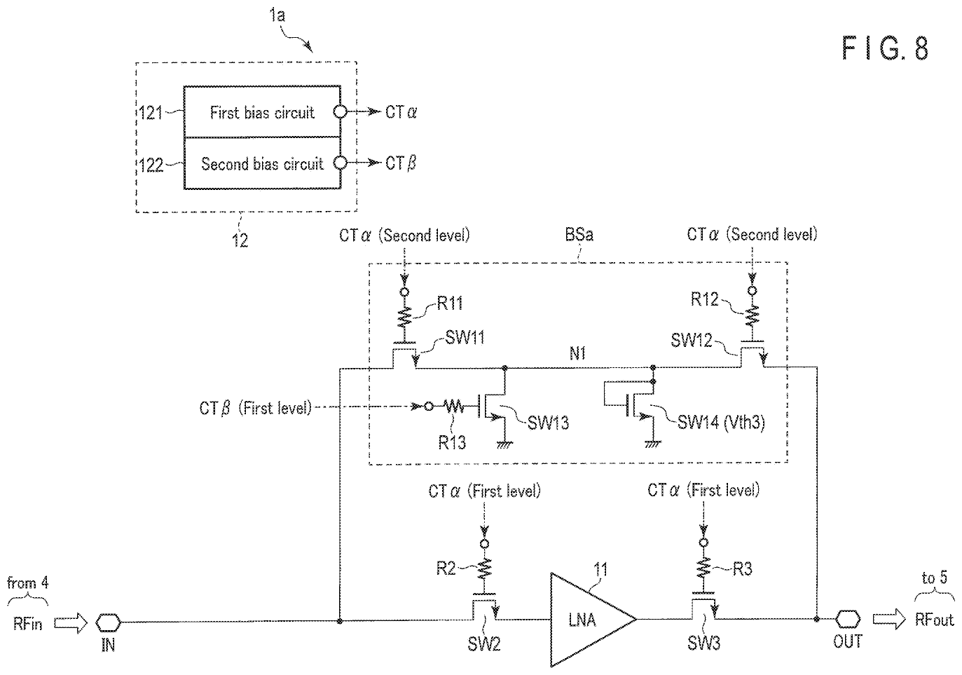

FIG. 8 shows an example of the circuit configuration of the amplifier circuit 1a according to the second embodiment.

The circuit configuration of the amplifier circuit 1a shown in FIG. 8 differs from that of the amplifier circuit 1 shown in FIG. 2 in that the amplifier circuit 1a includes a bypass switch BSa instead of the bypass switch BS. The bypass switch BSa includes a switch SW14 in addition to the structures included in the bypass switch BS.

The description of FIG. 2 applies to the configuration of the amplifier circuit 1a except that the amplifier circuit 1 is replaced with the amplifier circuit 1a and that the bypass switch BS is replaced with the bypass switch BSa. The switch SW14 will be described.

A first end of the switch SW14 is coupled to the node N1. A second end of the switch SW14 is, for example, grounded. Hereinafter, descriptions will be provided assuming that the second end of the switch SW14 is grounded so that a voltage of 0 V is applied to the second end. The gate of the switch SW14 is coupled to the node N1. In this way, the switch SW14 is diode-coupled to the node N1 in the forward direction.

While the bypass switch BSa is in the off-state, the first end and gate of the switch SW14 are grounded via the on-state switch SW13. Since the second end of the switch SW14 is also grounded, the switch SW14 is in the off-state.

While the bypass switch BSa is in the on-state, the switch SW14 can adjust the voltage of the radio-frequency signal RFin based on, for example, the voltage of the node N1 coupled to the first end of the switch SW14. Details will be described below. The switch SW14 is in the off-state while the voltage of the node N1 is smaller than a certain value and thus does not adjust the voltage of the radio-frequency signal RFin, but is in the on-state while the voltage of the node N1 is larger than or equal to the certain value and thus adjusts the voltage of the radio-frequency signal RFin.

The description of FIG. 3 applies to the threshold voltages of the switches SW11, SW12, and SW13 of the bypass switch BSa of the amplifier circuit 1a and to the voltages of the control signals CTα and CTβ. The threshold voltage of the switch SW14 will be described.

The threshold voltage of the switch SW14 is a voltage Vth3. In order to provide the switch SW14 with the above-described voltage adjustment function, the voltage Vth3 is, for example, smaller than the voltage Vth1. For example, (magnitude of voltage Vth3)/(magnitude of voltage Vth1) is not less than ⅓ and not more than ⅚. The voltage Vth3 may be equal to the voltage Vth2.

When the voltages Vth1, Vth2, VH, VL1, and VL2 are the specific values described in the first embodiment, the voltage Vth3 is, for example, 0.5 V or less, and more specifically, 0.3 V.

An operation of the amplifier circuit 1a according to the second embodiment will be described, focusing on differences from the operation of the amplifier circuit 1 according to the first embodiment. As in the example of FIG. 5, the case where the amplifier circuit 1a transmits, while in the bypass mode, a radio-frequency signal RFin from the terminal IN to the terminal OUT via the bypass switch BSa will be described.

First, the description of FIG. 5 applies except that the amplifier circuit 1 is replaced with the amplifier circuit 1a and that the bypass switch BS is replaced with the bypass switch BSa. Next, the switch SW14 while the radio-frequency signal RFin is transmitted via the bypass switch BSa will be described.

The voltage of the gate of the switch SW14 is the voltage VRF of the node N1 coupled to the gate of the switch SW14. The voltage VRF is also a potential difference between the gate and source of the switch SW14.

When the voltage VRF is smaller than the voltage Vth3, which is the threshold voltage of the switch SW14, the switch SW14 is in the off-state. In this case, the switch SW14 does not adjust the voltage of the radio-frequency signal RFin being transmitted to the node N1.

When the voltage VRF is larger than or equal to the voltage Vth3, the switch SW14 is in the on-state. Since a current flows out of the node N1 via the on-state switch SW14, the voltage VRF of the node N1 drops. The drop of the voltage VRF by the switch SW14 continues until, for example, the voltage VRF falls below the voltage Vth3. In this way, the voltage VRF is adjusted by the on-state switch SW14 and, for example, peaks of the voltage VRF on the high potential side is cut.

The voltage VRF accordingly adjusted by the switches SW13 and SW14 as appropriate is transmitted to the terminal OUT via the on-state switch SW12, and the radio-frequency signal RFout is output from the terminal OUT. The power relating to the adjusted radio-frequency signal RFout is smaller than the power relating to the unadjusted radio-frequency signal RFin.

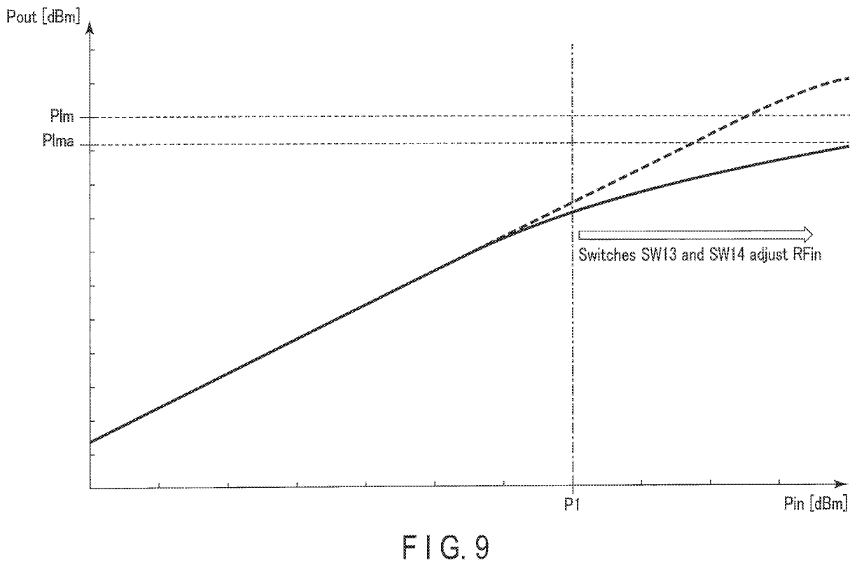

FIG. 9 shows an example of a graph in which the value of output power Pout when the radio-frequency signal RFin is transmitted via the bypass switch BSa in the amplifier circuit 1a according to the second embodiment is plotted while varying the value of input power Pin. The horizontal axis represents the value of the input power Pin. The vertical axis represents the value of the output power Pout. In FIG. 9, the graph is shown as a solid line. The graph shows values under the same conditions as those of the example of FIG. 6 regarding the common structures to the amplifier circuit 1a and the amplifier circuit 1 according to the first embodiment. The broken-line graph shown in FIG. 9 is the same as the broken-line graph shown in FIG. 6.

As shown in FIG. 9, when the value of the input power Pin is smaller than the value P1, the value of the output power Pout increases in accordance with a linear function as the value of the input power Pin increases, and the solid-line graph in the example of FIG. 9 substantially matches the solid-line graph in the example of FIG. 6. In contrast, when the value of the input power Pin is larger than or equal to P1, the graph is as follows. As described above, the switches SW13 and SW14 may adjust the radio-frequency signal RFin. Accordingly, as shown in FIG. 9, the increase in the value of the output power Pout relative to the increase in the value of the input power Pin becomes smaller, and the value of the output power Pout does not exceed a certain value Plma even though the value of the input power Pin increases. Plma is smaller than Plm.

With reference to FIGS. 8 and 9, the case where the bypass switch BSa includes switches SW13 and SW14 has been described. However, the present embodiment is not limited to this. The bypass switch BSa may include the switch SW13x described in the comparative example of the first embodiment, instead of the switch SW13. In this case, the control signal generator 12 does not have to include the second bias circuit 122. Even in this case, the switch SW14 can adjust the radio-frequency signal RFin.

As described above, in the amplifier circuit 1a according to the second embodiment, not only the switch SW13, but also the switch SW14 adjusts the radio-frequency signal RFin as appropriate when the radio-frequency signal RFin is transmitted from the terminal IN to the terminal OUT via the bypass switch BSa. Specifically, when the voltage VRF of the gate of the switch SW14 is larger than or equal to the voltage Vth3, the switch SW14 is in the on-state and, thus, the voltage VRF of the node N1 is lowered.

Accordingly, in the amplifier circuit 1a according to the second embodiment, not only the switch SW13, but also the switch SW14 can adjust the radio-frequency signal RFin. Consequently, as shown in FIG. 9, the increase in the output power Pout relative to the increase in the input power Pin may be suppressed in comparison to the case of the amplifier circuit 1 according to the first embodiment.

### Third Embodiment

An amplifier circuit 1b according to a third embodiment will be described below.

A configuration of the amplifier circuit 1b according to the third embodiment will be described, focusing on differences from the configuration of the amplifier circuit 1a according to the second embodiment.

The description of the amplifier circuit 1 with reference to FIG. 1 applies to the amplifier circuit 1b. Specifically, the description of FIG. 1 applies except that the amplifier circuit 1 is replaced with the amplifier circuit 1b.

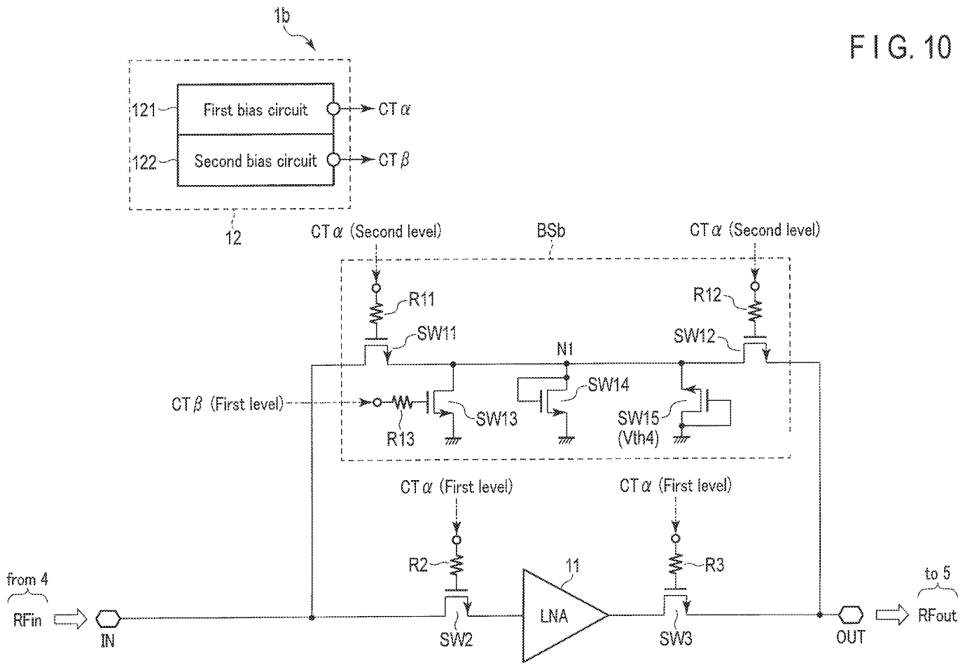

FIG. 10 shows an example of the circuit configuration of the amplifier circuit 1b according to the third embodiment.

The circuit configuration of the amplifier circuit 1b shown in FIG. 10 differs from that of the amplifier circuit 1a shown in FIG. 8 in that the amplifier circuit 1b includes a bypass switch BSb instead of the bypass switch BSa. The bypass switch BSb includes a switch SW15 in addition to the structures included in the bypass switch BSa.

The description of the configuration of the amplifier circuit 1a in the second embodiment in connection with FIG. 2 applies to the configuration of the amplifier circuit 1b except that the amplifier circuit 1a is replaced with the amplifier circuit 1b and that the bypass switch BSa is replaced with the bypass switch BSb. The switch SW15 will be described.

A first end of the switch SW15 is coupled to the node N1. A second end of the switch SW15 is, for example, grounded. Hereinafter, descriptions will be provided assuming that the second end of the switch SW15 is grounded so that a voltage of 0 V is applied to the second end. The gate of the switch SW15 is coupled to the second end of the switch SW15. In this way, the switch SW15 is diode-coupled to the node N1 in the backward direction.

While the bypass switch BSb is in the off-state, the first end of the switch SW15 is grounded via the on-state switch SW13. Since the second end and gate of the switch SW15 are also grounded, the switch SW15 is in the off-state.

While the bypass switch BSb is in the on-state, the switch SW15 can adjust the voltage of the radio-frequency signal RFin based on, for example, the voltage of the node N1 coupled to the first end of the switch SW15. Details will be described below. The switch SW15 is in the off-state while the voltage of the node N1 exceeds a certain value and thus does not adjust the voltage of the radio-frequency signal RFin, but is in the on-state while the voltage of the node N1 is smaller than or equal to the certain value and thus adjusts the voltage of the radio-frequency signal RFin.

The description provided in the second embodiment in connection with FIG. 3 applies to the threshold voltages of the switches SW11, SW12, SW13, and SW14 of the bypass switch BSb of the amplifier circuit 1b and to the voltages of the control signals CTα and CTβ. The threshold voltage of the switch SW15 will be described.

The threshold voltage of the switch SW15 is a voltage Vth4. In order to provide the switch SW15 with the above-described voltage adjustment function, the voltage Vth4 is, for example, smaller than the voltage Vth1. For example, (magnitude of voltage Vth4)/(magnitude of voltage Vth1) is not less than ⅓ and not more than ⅚. The voltage Vth4 may be equal to the voltage Vth2 and/or voltage Vth3.

When the voltages Vth1, Vth2, Vth3, VH, VL1, and VL2 are the specific values described in the first embodiment and the second embodiment, the voltage Vth4 is, for example, 0.5 V or less, and more specifically, 0.3 V.

An operation of the amplifier circuit 1b according to the third embodiment will be described, focusing on differences from the operation of the amplifier circuit 1a according to the second embodiment. As in the example of FIG. 5, the case where the amplifier circuit 1b transmits, while in the bypass mode, a radio-frequency signal RFin from the terminal IN to the terminal OUT via the bypass switch BSb will be described.

First, the description of the operation of the amplifier circuit 1a provided in the second embodiment in connection with FIG. 5 applies except that the amplifier circuit 1a is replaced with the amplifier circuit 1b and that the bypass switch BSa is replaced with the bypass switch BSb. Next, the switch SW15 while the radio-frequency signal RFin is transmitted via the bypass switch BSb will be described.

The voltage of the first end of the switch SW15 is the voltage VRF of the node N1 coupled to the first end of the switch SW15. The second end and gate of the switch SW15 are grounded. Therefore, the switch SW15 operates as follows.

When the voltage VRF is not lower than 0 V by the voltage Vth4, which is the threshold voltage of the switch SW15, or more, the switch SW15 is in the off-state. In this case, the switch SW15 does not adjust the voltage of the radio-frequency signal RFin being transmitted to the node N1.

When the voltage VRF is lower than 0 V by the voltage Vth4 or more, the switch SW15 is in the on-state. Since a current flows into the node N1 via the on-state switch SW15, the voltage VRF of the node N1 rises. The rise of the voltage VRF by the switch SW15 continues until, for example, the voltage VRF becomes no longer lower than 0 V by the voltage Vth4 or more. In this way, the voltage VRF is adjusted by the on-state switch SW15 and, for example, peaks of the voltage VRF on the low potential side is cut.

The voltage VRF accordingly adjusted by the switches SW13, SW14, and SW15 as appropriate is transmitted to the terminal OUT via the on-state switch SW12, and the radio-frequency signal RFout is output from the terminal OUT. The power relating to the adjusted radio-frequency signal RFout is smaller than the power relating to the unadjusted radio-frequency signal RFin.

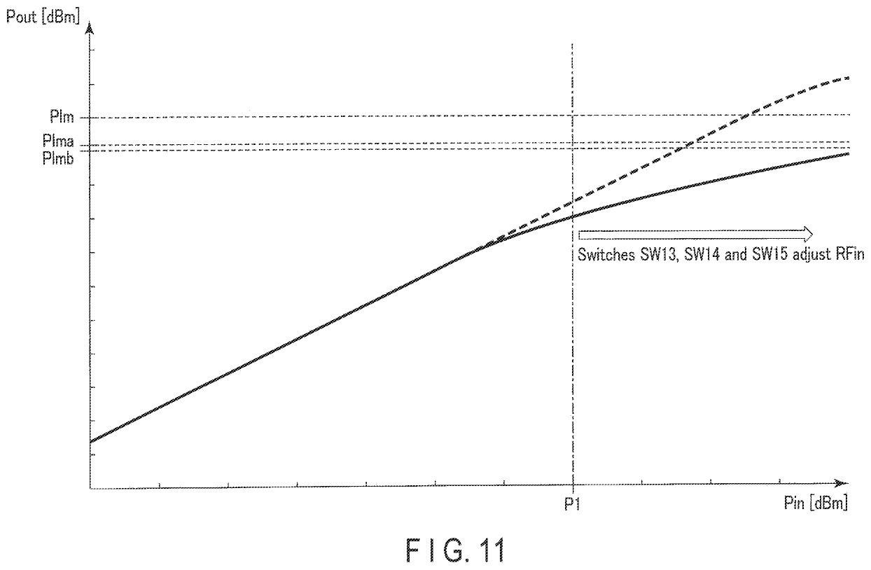

FIG. 11 shows an example of a graph in which the value of output power Pout when the radio-frequency signal RFin is transmitted via the bypass switch BSb in the amplifier circuit 1b according to the third embodiment is plotted while varying the value of input power Pin. The horizontal axis represents the value of the input power Pin. The vertical axis represents the value of the output power Pout. In FIG. 11, the graph is shown as a solid line. The graph shows values under the same conditions as those of the example of FIG. 9 regarding the common structures to the amplifier circuit 1b and the amplifier circuit 1a according to the second embodiment. The broken-line graph shown in FIG. 11 is the same as the broken-line graph shown in FIG. 6.

As shown in FIG. 11, when the value of the input power Pin is smaller than the value P1, the value of the output power Pout increases in accordance with a linear function as the value of the input power Pin increases, and the solid-line graph in the example of FIG. 11 substantially matches the solid-line graph in the example of FIG. 6.

In contrast, when the value of the input power Pin is larger than or equal to P1, the graph is as follows. As described above, the switches SW13, SW14, and SW15 adjust the radio-frequency signal RFin. Accordingly, as shown in FIG. 11, the increase in the value of the output power Pout relative to the increase in the value of the input power Pin becomes smaller, and the value of the output power Pout does not exceed a certain value Plmb even though the value of the input power Pin increases. Plmb is smaller than Plma.

With reference to FIGS. 10 and 11, the case where the bypass switch BSb includes switches SW13, SW14, and SW15 has been described. However, the present embodiment is not limited to this. The bypass switch BSb may include the switch SW13x described in the comparative example of the first embodiment, instead of the switch SW13. In this case, the control signal generator 12 does not have to include the second bias circuit 122. In addition, the bypass switch BSb does not have to include the switch SW14. Even in this case, at least the switch SW15 can adjust the radio-frequency signal RFin.

As described above, in the amplifier circuit 1b according to the third embodiment, not only the switches SW13 and SW14, but also the switch SW15 adjusts the radio-frequency signal RFin as appropriate when the radio-frequency signal RFin is transmitted from the terminal IN to the terminal OUT via the bypass switch BSb. Specifically, when the voltage VRF of the node N1 is lower than 0 V by the voltage Vth4 or more, the switch SW15 is in the on-state and, thus, the voltage VRF of the node N1 is raised.

Accordingly, in the amplifier circuit 1b according to the third embodiment, not only the switches SW13 and SW14, but also the switch SW15 can adjust the radio-frequency signal RFin. Consequently, as shown in FIG. 11, the increase in the output power Pout relative to the increase in the input power Pin is suppressed in comparison to the case of the amplifier circuit 1a according to the second embodiment.

### Other Embodiments

Herein, the term “couple” refers to electrical coupling, and does not exclude intervention of another component.

Herein, expressions such as “the same”, “match”, “constant”, and “maintain” are used with an intention of tolerating an error in a design range when the technique described in each embodiment is implemented. The same applies to the above expressions accompanied by “substantially”, such as “substantially the same”. Expressions such as a voltage being applied or supplied are used with an intention of including both control to apply or supply the voltage and actual application or supply of the voltage. Application or supply of a voltage may include application or supply of, for example, 0 V.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a radio-frequency amplifier circuit;
a first switch coupled between a first node and an input end of the radio-frequency amplifier circuit;
a second switch coupled between the first node and an output end of the radio-frequency amplifier circuit; and
a third switch coupled between the first node and a reference potential node, a control end of the third switch being coupled to one of the first node and the reference potential node.

2. The device according to claim 1, wherein
the control end of the third switch is coupled to the first node, and
the semiconductor device further comprises a fourth switch coupled between the first node and the reference potential node, a control end of the fourth switch being coupled to the reference potential node.

3. The device according to claim 1, further comprising:
a fourth switch coupled between the first node and the reference potential node; and
a first circuit configured to generate and output a first signal, wherein
the first signal is input to a control end of the fourth switch, and
a threshold voltage of the fourth switch is smaller than threshold voltages of the first switch and the second switch.

4. The device according to claim 2, further comprising:
a fifth switch coupled between the first node and the reference potential node; and
a first circuit configured to generate and output a first signal, wherein
the first signal is input to a control end of the fifth switch, and
a threshold voltage of the fifth switch is smaller than threshold voltages of the first switch and the second switch.

5. The device according to claim 1, further comprising:
a fourth switch coupled between the first node and the reference potential node;
a first circuit configured to generate and output a first signal; and
a second circuit configured to generate and output a second signal, wherein
the first signal is input to control ends of the first switch and the second switch,
the second signal is input to a control end of the fourth switch,
a voltage of the first signal switches between a first level and a second level, the second level being higher than the first level, and
a voltage of the second signal switches between a third level and a fourth level, the fourth level being higher than the third level, and the third level being higher than the first level.

6. The device according to claim 2, further comprising:
a fifth switch coupled between the first node and the reference potential node;
a first circuit configured to generate and output a first signal; and
a second circuit configured to generate and output a second signal, wherein
the first signal is input to control ends of the first switch and the second switch,
the second signal is input to a control end of the fifth switch,
a voltage of the first signal switches between a first level and a second level, the second level being higher than the first level, and
a voltage of the second signal switches between a third level and a fourth level, the fourth level being higher than the third level, and the third level being higher than the first level.

7. The device according to claim 1, wherein a threshold voltage of the third switch is smaller than threshold voltages of the first switch and the second switch.

8. The device according to claim 2, wherein a threshold voltage of the third switch and a threshold voltage of the fourth switch are each smaller than threshold voltages of the first switch and the second switch.

9. A semiconductor device comprising:
a radio-frequency amplifier circuit; and
a first circuit including a first switch coupled between a first node and an input end of the radio-frequency amplifier circuit, a second switch coupled between the first node and an output end of the radio-frequency amplifier circuit, and a third switch coupled between the first node and a reference potential node, the first circuit being configured to electrically couple the first node to the reference potential node via the third switch while the first switch and the second switch are ON.

10. The device according to claim 9, wherein a control end of the third switch is coupled to one of the first node and the reference potential node.

11. The device according to claim 10, wherein
the control end of the third switch is coupled to the first node, and
the first circuit further comprises a fourth switch coupled between the first node and the reference potential node, a control end of the fourth switch being coupled to the reference potential node.

12. The device according to claim 11, wherein the first circuit is further configured to electrically couple the first node to the reference potential node via the fourth switch while the first switch and the second switch are ON.

13. The device according to claim 9, further comprising:
a second circuit configured to generate and output a first signal; and
a third circuit configured to generate and output a second signal, wherein
the first signal is input to control ends of the first switch and the second switch,
the second signal is input to a control end of the third switch,
a voltage of the first signal switches between a first level and a second level, the second level being higher than the first level, and
a voltage of the second signal switches between a third level and a fourth level, the fourth level being higher than the third level, and the third level being higher than the first level.

14. The device according to claim 13, wherein the first circuit further comprises a fourth switch coupled between the first node and the reference potential node, a control end of the fourth switch being coupled to one of the first node and the reference potential node.

15. The device according to claim 14, wherein the first circuit is further configured to electrically couple the first node to the reference potential node via the fourth switch while the first switch and the second switch are ON.

16. The device according to claim 14, wherein
the control end of the fourth switch is coupled to the first node,
the first circuit further comprises a fifth switch coupled between the first node and the reference potential node, a control end of the fifth switch being coupled to the reference potential node, and
the first circuit is further configured to electrically couple the first node to the reference potential node via the fourth switch and the fifth switch while the first switch and the second switch are ON.

17. The device according to claim 9, wherein a threshold voltage of the third switch is smaller than threshold voltages of the first switch and the second switch.

18. The device according to claim 13, wherein a threshold voltage of the third switch is smaller than threshold voltages of the first switch and the second switch.

19. The device according to claim 14, wherein a threshold voltage of the third switch and a threshold voltage of the fourth switch are each smaller than threshold voltages of the first switch and the second switch.

20. The device according to claim 16, wherein a threshold voltage of the third switch, a threshold voltage of the fourth switch, and a threshold voltage of the fifth switch are each smaller than threshold voltages of the first switch and the second switch.
